(19) United States
(12) Patent Application Publication
(10) Pub. No.: US 2025/0210936 A1
(43) Pub. Date: Jun. 26, 2025

(54) VERTICAL-EMITTING SEMICONDUCTOR LASER COMPONENT, ARRAY, AND CHIP HAVING PREFERRED DIRECTION

(71) Applicant: TRUMPF Photonic Components GmbH, Ulm (DE)

(72) Inventors: Holger Joachim Mönch, Vaals (NL); Sven Bader, Neu-Ulm (DE); Alexander Weigl, Günzburg (DE); Markus Herper, Aachen (DE)

(21) Appl. No.: 19/079,499

(22) Filed: Mar. 14, 2025

Related U.S. Application Data
(63) Continuation of application No. PCT/EP2023/075322, filed on Sep. 14, 2023.

(30) Foreign Application Priority Data
Sep. 16, 2022 (DE) 10 2022 123 833.4
Oct. 17, 2022 (DE) 10 2022 127 126.9

(51) Int. Cl. H01S 5/042; H01S 5/183; H01S 5/42

(52) U.S. Cl. CPC H01S 5/0421; H01S 5/1835; H01S 5/18352; H01S 5/423

(57) ABSTRACT

A vertical-emitting semiconductor laser component includes a semiconductor material having an optical axis, a mesa for emitting light in a light emission direction, and a contact for electrically contacting the mesa. The contact has a contact opening arranged along a first direction. The optical axis is arranged along the first direction.

### CROSS REFERENCE TO RELATED APPLICATIONS

This application is a continuation of International Application No. PCT/EP2023/075322 (WO 2024/056811 A1), filed on Sep. 14, 2023, and claims benefit to German Patent Application No. DE 10 2022 127 126.9, filed on Oct. 17, 2022 and to German Patent Application No. DE 10 2022 123 833.4, filed on Sep. 16, 2022. The aforementioned applications are hereby incorporated by reference herein.

### FIELD

Embodiments of the present invention relate to a vertical-emitting semiconductor laser component. Embodiments of the present invention also relate to an array and a chip.

### BACKGROUND

Polarized laser radiation is used, for example, in the area of sensors and illumination. The laser outputs required for this purpose usually require an array having a plurality of vertical-emitting semiconductor laser components and/or numerous mesas. For applications of polarized laser radiation from a vertical-emitting semiconductor laser component, in particular a “vertical-cavity surface-emitting laser”, abbreviated VCSEL, and/or a VCSEL array, it is advantageous if the polarization orientations of the emitted laser beams of all mesas are identical. A surface grating has only been used up to this point to stabilize the desired polarization of a single mesa, wherein the polarization of multiple mesas has not been considered up to this point.

However, even if multiple mesas have the same surface grating, it has been shown in experiments that some mesas of the array emit light having a polarization pivoted in relation to the surface grating. Furthermore, it has been established that the polarization orientation of the emitted laser radiation of the array and/or the individual mesas is pivoted by a few degrees in relation to a mean value or a desired position of the polarization orientation. The degree of polarization and the contrast thus decreases disadvantageously in different applications.

### SUMMARY

Embodiments of the present invention provide a vertical-emitting semiconductor laser component. The vertical-emitting semiconductor laser component includes a semiconductor material having an optical axis, a mesa for emitting light in a light emission direction, and a contact for electrically contacting the mesa. The contact has a contact opening arranged along a first direction. The optical axis is arranged along the first direction.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a vertical-emitting semiconductor laser component having a contact opening oriented in a preferred direction according to some embodiments;

FIG. 2 shows a vertical-emitting semiconductor laser component having a surface grating oriented in a preferred direction according to some embodiments;

FIG. 3 shows a vertical-emitting semiconductor laser component having contact openings oriented perpendicular to the preferred direction according to some embodiments;

FIG. 4 shows a vertical-emitting semiconductor laser component having differently dimensioned contact connections according to some embodiments;

FIG. 5 shows a vertical-emitting semiconductor laser component having differently dimensioned contact connections according to some embodiments;

FIG. 6 shows a vertical-emitting semiconductor laser component having an oval mesa and an oval trench according to some embodiments;

FIG. 7 shows an array having two rows of vertical-emitting semiconductor laser components according to some embodiments;

FIG. 8 shows an array having multiple individually addressable array sections according to some embodiments;

FIG. 9 shows an array having intersecting conductor tracks according to some embodiments;

FIG. 10 shows the array from FIG. 9 in a top view along the light emission direction according to some embodiments;

FIG. 11 shows a chip having a vertical-emitting semiconductor laser component according to some embodiments; and

FIG. 12 shows the chip of FIG. 10 in a top view according to some embodiments.

### DETAILED DESCRIPTION

Embodiments of the present invention provide an improved vertical-emitting semiconductor laser component. Embodiments of the invention also provide an improved array having such a semiconductor laser component. In addition, embodiments of the invention provide an improved chip having such a vertical-emitting semiconductor laser component.

The vertical-emitting semiconductor laser component and preferred refinements thereof are preferably designed and intended for use in the array according to embodiments of the invention and the chip according to embodiments of the invention, and in preferred refinements thereof. The array according to embodiments of the invention is preferably designed and intended for use in the chip according to embodiments of the invention, and in preferred refinements thereof.

All features of the subjects described here and also the claimed subjects are usable both in an isolated manner and in combination with one another, are compatible with one another, and are intended and usable for refinement with one another, if no logical contradiction results, and are hereby disclosed in this regard. Hereinafter, any reference to a subject or a feature (including the indefinite articles “a” and “an” and the definite article “the”), two subjects or two features, or another number of subjects or features, if not expressly indicated otherwise or a logical contradiction results, is to be understood to mean that the presence of further such subjects and features is not excluded. The reference signs in the claims are not to be understood as restrictive, but serve only for better readability of the claims.

According to a first aspect of the invention, the vertical-emitting semiconductor laser component comprises a semiconductor material having an optical axis, as well as a mesa for emitting light and a contact for electrically contacting the mesa. The contact comprises a contact opening, wherein the contact opening is arranged along a preferred direction. The optical axis is arranged along the preferred direction according to the first aspect of the invention.

According to a second aspect of the invention, the vertical-emitting semiconductor laser component comprises a mesa for emitting light in a light emission direction and a contact for electrically contacting the mesa. The contact comprises a contact opening. Moreover, the vertical-emitting semiconductor laser component according to the second aspect of the invention comprises a surface grating for polarizing the light. The surface grating is preferably arranged in the light emission direction above the mesa. The contact opening is arranged along a preferred direction. According to the second aspect of the invention, the surface grating is arranged perpendicular or parallel to the preferred direction.

According to a third aspect of the invention, the vertical-emitting semiconductor laser component comprises a mesa for emitting light in a light emission direction and a contact for electrically contacting the mesa. The contact comprises a contact opening, wherein the contact opening is arranged along a preferred direction. The mesa according to the third aspect of the invention has an oval shape in a top view along the light emission direction, which tapers in at least one area perpendicular or parallel to the preferred direction.

According to a fourth aspect of the invention, the array comprises a plurality of vertical-emitting semiconductor laser components, at least one semiconductor laser component of which, preferably all vertical-emitting semiconductor laser components, is/are designed according to embodiments of the invention.

According to a fifth aspect of the invention, the chip comprises a vertical-emitting semiconductor laser component according to embodiments of the invention and/or an array according to embodiments of the invention. The chip has a height along the light emission direction, as well as a width and a length perpendicular to the light emission direction, wherein the length is greater than the width and the length and/or the width are arranged along the preferred direction.

Preferably, the vertical-emitting semiconductor laser component comprises a semiconductor material having an optical axis. Preferably, the optical axis is arranged along the preferred direction or perpendicular or at 45° to the preferred direction. Preferably, the optical axis is not arranged at any angle in relation to the preferred direction other than 180° or 90° or 45°.

Preferably, the vertical-emitting semiconductor laser component comprises a surface grating for polarizing the light, which is particularly preferably arranged in the light emission direction above the mesa. The surface grating is preferably arranged perpendicular or parallel or at 45° to the preferred direction. Preferably, the surface grating is not arranged at any angle in relation to the preferred direction other than 180° or 90° or 45°.

Preferably, the mesa has an oval shape in a top view along the light emission direction, which particularly preferably tapers in at least one area perpendicular or parallel or at 45° to the preferred direction. Preferably, the oval shape does not taper at any angle in relation to the preferred direction other than 180° or 90° or 45°.

The “vertical-emitting semiconductor laser component” is in particular a laser diode. The vertical-emitting semiconductor laser component is preferably a surface emitter. The vertical-emitting semiconductor laser component is preferably a “vertical-cavity surface-emitting laser”, abbreviated VCSEL. In particular, the light is emitted perpendicular to the plane of the chip in the VCSEL. This is in contrast to edge-emitting laser diodes, in which the light is emitted at one or two flanks of the chip.

The “semiconductor material” is in particular a solid, the electrical conductivity of which is between >10⁴ S/cm and <10⁻⁸ S/cm. The semiconductor material comprises or consists in particular of an element and/or a species selected from the group comprising or consisting of silicon, gallium, indium, germanium, and arsenic. The semiconductor material preferably comprises gallium arsenide or consists of gallium arsenide.

The “optical axis” is in particular a crystal axis of a crystalline material. The optical axis is preferably the direction of an optically anisotropic and preferably birefringent crystalline material along which a polarization component of the light experiences the same index of refraction. The optical axis is preferably arranged in the direction of a unique main index of refraction, in particular in a uniaxial crystal, for example in the whorled crystal systems having the geometries trigonal or tetragonal or hexagonal. A light beam preferably behaves along the optical axis as in an isotropic crystal. The optical axis is preferably oriented identically along an epitaxial layer stack in each layer of the layer stack.

The “mesa” is preferably formed as a protrusion having a planar surface and steep flanks.

The “light” is preferably laser light. The light preferably has a wavelength of 500 nm to 1600 nm, particularly preferably of 900 nm to 1500 nm, most preferably of 1300 nm to 1500 nm.

The “light emission direction” is in particular the direction in which the light emerging from the mesa is emitted. The light emission direction is preferably perpendicular to the surface of the chip and particularly preferably perpendicular to a planar surface of the mesa.

The “contact” is designed in particular for conducting current, preferably for feeding electric energy into the mesa and/or for electrical contacting between the mesa and an energy source and/or between two mesas. The contact is preferably a p-contact. Alternatively, the contact is preferably an n-contact. The contact is in particular annular. Preferably, the contact has an open shape. The contact is preferably designed in the form of a ring opened once or multiple times in a top view along the light emission direction. The contact can be formed from a plurality of contact sections. The contact is typically a metal contact and is formed by metal layers. The contact advantageously has improved processability due to the above-mentioned refinements.

The “contact opening” is preferably a recess, in particular a taper, or an opening of the contact. Preferably, less material of the contact is applied in the area of the contact opening or the contact opening is completely free of the material of the contact. The contact opening is preferably electrically insulating, so that no current is conducted in particular in the area of the contact opening. The contact opening is preferably elongated, wherein a length of the contact opening in a longitudinal direction is greater than a width of the contact opening in a width direction.

The alignment “along” a direction, in particular the preferred direction or the light emission direction, is in particular a parallel alignment. This means in particular that an extension direction of a material feature, such as the longitudinal direction of the contact opening in particular, is the same, for example, as the preferred direction.

The “surface grating” is preferably an optically active grating, in particular a polarization grating for polarizing the light. The surface grating preferably has two polarization orientations, wherein it particularly preferably has a different reflectivity for the two polarization orientations. The surface grating preferably selects a desired polarization orientation, particularly preferably via the reflectivity. The surface grating is designed in particular so that the reflection of a desired polarization is maximized and the reflection perpendicular to the desired polarization is minimized. The surface grating is preferably designed so that a reflection difference between the two polarization orientations is maximized. The surface grating is preferably arranged on an upper Bragg mirror of the VCSEL. The surface grating is preferably applied to the entire wafer and has the same polarization orientation everywhere. Alternatively, the surface grating is preferably arranged in the area of the mesa, particularly preferably only in the area of the mesa. The surface grating is preferably aligned along the crystal axes of the semiconductor material gallium arsenide. In particular, the surface grating is etched into the gallium arsenide material and forms structures of 50 nm to 100 nm depth along the light emission direction, preferably 70 nm. The structures preferably have a periodic spacing perpendicular to the light emission direction of 100 nm to 200 nm, particularly preferably 140 nm.

The “oval shape” is in particular an arbitrary oval shape which does not have an axis of symmetry. The oval shape is preferably symmetrical to at least one axis of symmetry. The oval shape is preferably a closed convex curve, which is continuously differentiable twice, in a plane. The oval shape is in particular an ellipse shape. The oval shape is preferably not circular. The oval shape preferably has two opposite areas which taper perpendicular to or along the preferred direction. The oval shape is preferably a planar round convex shape similar to the profile of an eye. The oval shape is preferably eye-shaped.

The “trench” is in particular a depression, preferably a depression in the light emission direction. The trench is preferably a depression in the layer stack. The trench preferably comprises a regular arrangement of depressions. The trench is preferably formed to shape the mesa, wherein preferably an inner contour of the trench defines the shape of the mesa.

The “hexagonal” arrangement is preferably a honeycomb-like arrangement. In the hexagonal arrangement, the vertical-emitting semiconductor laser components are preferably arranged in a regular hexagonal parquet, particularly preferably continuously. Preferably, adjacent vertical-emitting semiconductor laser components are connected via complete edges in the hexagonal parquet, and particularly preferably not via corners or edge parts.

The vertical-emitting semiconductor laser component preferably comprises a further contact opening, particularly preferably a plurality of further contact openings. The contact preferably comprises the further contact opening. The further contact opening is in particular arranged along the preferred direction or perpendicular to the preferred direction or at 45° to the preferred direction. The further contact opening is preferably structurally identical to the contact opening and in particular is designed geometrically identical and is preferably congruent with the contact opening by rotation and translation. The contact preferably has a plurality of contact openings, which are each arranged along the preferred direction and/or perpendicular and/or at 45° to the preferred direction.

The vertical-emitting semiconductor laser component preferably comprises a trench, which particularly preferably at least partially encloses the mesa, most preferably completely encloses it.

The contact preferably comprises a plurality of contact connections. In particular, at least two contact connections of the plurality of contact connections are dimensioned differently from one another.

The “contact connection” is preferably a contact section of the contact. The contact connection preferably comprises a via or is formed as a via. The via is preferably a p-via.

One of the differently dimensioned contact connections is preferably arranged along the preferred direction or perpendicular or at a 45° angle to the preferred direction. Preferably, two opposing contact connections are dimensioned substantially identically. Preferably, two opposing contact connections spaced apart from one another perpendicularly to the light emission direction are dimensioned substantially identically. “Substantially” in particular comprises the typical manufacturing tolerances. Preferably, the contact comprises a plurality of contact connections which are each arranged along the preferred direction and/or perpendicular and/or at 45° to the preferred direction.

In particular, the trench has an oval shape in a top view along the light emission direction, which preferably tapers in at least one area perpendicular to or along the preferred direction. Alternatively, the trench preferably has a circular shape in a top view along the light emission direction. The shape of an optical aperture is preferably determined by the shape of the mesa.

A curve course of the oval shape of the trench preferably corresponds to a curve course of the oval shape of the mesa. A curve course of the contact preferably corresponds to the curve course of the mesa. The contact particularly preferably has an oval shape in a top view along the light emission direction, which preferably tapers in at least one area perpendicular to or along the preferred direction. The curve course of the oval shape of the contact preferably corresponds to the curve course of the oval shape of the mesa.

The vertical-emitting semiconductor laser component preferably comprises an optical aperture which is designed for emitting light. Fundamentally and preferably, a shape of the optical aperture is substantially identical to the shape of the mesa. In particular, this is the result of an oxidation process in which the optical aperture is formed. The shape of the optical aperture preferably deviates slightly from the shape of the mesa. In particular, in an oval mesa, the tapering areas are smoother at the optical aperture, wherein preferably tips of the tapering areas of the optical aperture are more rounded in comparison to tips of the tapering areas of the mesa. The ovality of the shape of the optical aperture preferably increases in comparison to the shape of the mesa, in particular, the curvature of the curve course is greater here in a top view along the light emission direction of the optical aperture than the curvature of the curve course in a top view along the light emission direction of the mesa, preferably in opposing sections of the respective curves.

In a preferred array, the vertical-emitting semiconductor laser components are arranged substantially in an equilateral triangle in a top view along the light emission direction, preferably in an exactly equilateral triangle. “Substantially” comprises the typical manufacturing tolerances and is in particular subject to partial deviations from the exact equilateral shape of up to 25%, especially in the case of strongly oval shapes.

The vertical-emitting semiconductor laser components are preferably arranged hexagonally in relation to one another in a top view along the light emission direction.

The vertical-emitting semiconductor laser components are preferably arranged rectangularly in relation to one another in a top view along the light emission direction.

The “rectangular” arrangement is preferably a square arrangement. In the rectangular arrangement, the vertical-emitting semiconductor laser components are preferably arranged in a square parquet. In the square parquet, adjacent vertical-emitting semiconductor laser components are preferably connected via complete edges, and particularly preferably not via corners or edge parts.

Preferably, an array comprises at least four vertical-emitting semiconductor laser components. The four vertical-emitting semiconductor laser components, preferably all vertical-emitting semiconductor laser components, preferably comprise two contact connections. In particular, vertical-emitting semiconductor laser components can however also comprise only one contact connection in the marginal areas of the array close to the edges.

Preferably, in each case two opposing contact connections of two semiconductor laser components are connected to one another via a conductor track. The “conductor tracks” are in particular electrically conductive connections having a two-dimensional course in a plane. The conductor tracks are preferably designed for connecting the vertical-emitting semiconductor laser components with one another and/or for connecting vertical-emitting semiconductor laser components to a power source. The conductor tracks are preferably designed to transmit electric current. The conductor tracks are preferably designed for temperature transfer.

Intersecting conductor tracks are preferably spaced apart from one another in the light emission direction at least within an intersection area and are particularly preferably arranged offset lying one on top of another. Preferably, the conductor tracks intersect at a 90° angle or at a 45° angle. In particular, the intersecting conductor tracks are galvanically separated from one another.

The “intersection area” is preferably an area in which two conductor tracks are arranged lying one on top of another, thus intersect in other words, wherein one conductor track is arranged like a bridge over another conductor track. Preferably, no transmission of current takes place between the intersecting conductor tracks within the intersection area. The intersection area is particularly preferably electrically insulating, so that most preferably no current is transmitted between the intersecting conductor tracks. Preferably, no temperature transfer takes place between the intersecting conductor tracks within the intersection area, or at least a significantly lesser temperature transfer than along the conductor tracks. The intersection area is particularly preferably thermally insulating, so that heat is not transferred between intersecting conductor tracks, or at least significantly less heat is transferred than along the conductor tracks. The conductor tracks preferably form a fabric-like structure.

The array preferably comprises a plurality of individually addressable array sections, preferably having at least one vertical-emitting semiconductor laser component. The array sections preferably have a different polarization, in particular a polarization pivoted by 90°. The vertical-emitting semiconductor laser components of a single array section preferably have a uniform polarization.

The array preferably comprises at least two rows of vertical-emitting semiconductor laser components, which rows are particularly preferably arranged parallel to one another. The rows can represent array sections. The contact openings of all vertical-emitting semiconductor laser components of a row are preferably arranged directly one on top of another along the preferred direction. The rows are preferably arranged offset in relation to one another in the hexagonal arrangement. Preferably, four vertical-emitting semiconductor laser components are arranged at the corners of the rectangle in the rectangular arrangement, wherein particularly preferably each two adjacent vertical-emitting semiconductor laser components are arranged in a row.

It has been shown in experiments that multiple advantageous effects result due to all of the above-mentioned features and combinations of features, which contribute to improving the vertical-emitting semiconductor laser component, the array, and the chip.

Numerous effects which have an influence on the birefringence in the mesa and therefore on the polarization orientation are advantageously bundled by the fixed orientation relative to the preferred direction. These effects thus particularly advantageously act in the same direction. The effects are thus in particular bundled and guided in one direction.

It has proven to be significantly more advantageous to align all effects in parallel than to undertake the attempt to produce an alignment of the effects which cancels out as much as possible or is directed in opposite directions, especially because even minor deviations from a mutually canceling orientation of the effects results in uncontrolled overall behavior.

For example, mechanical forces and/or thermally induced stress effects are bundled in one direction due to the orientation in the preferred direction in their effect on the vertical-emitting semiconductor laser component, the array, and/or the chip, so that the polarization orientation of the mesa or the mesas is influenced in the same manner and to a very similar to identical extent. In particular, the emitted light thus has a more homogeneous polarization. It has been observed that mechanical stress only changes the birefringence, thus the wavelength spacing of the two polarization modes, which thus experience a differing spectral amplification. The polarization modes advantageously become farther away from one another, so that the nondominant mode is minimized by obstructing the threshold increase.

In addition, the service life is advantageously extended, since possible stress-induced material damage such as microcracks form almost exclusively in a specific orientation and do not propagate in an unordered manner.

Providing an oval mesa and therefore an oval optical aperture particularly advantageously results in a more uniform polarization, since modes are preferably formed in the desired polarization orientation due to an oval geometry. In addition, the oval mesa changes the surroundings of the laser and therefore the tensions in the crystal, wherein the tension has an influence on the birefringence, so that the polarization becomes more homogeneous due to tension-induced rectification.

In addition, it has been established that in particular also the arrangement of multiple mesas in an array has an effect on the performance due to different effects, in particular if the etched areas have different widths in different directions, as is the case, for example, with closely adjacent mesas.

The parallel alignment of all effects advantageously ensures that specific effects are amplified. For example, a threshold current minimum of the desired polarization is better defined and more strongly pronounced, which results in a further improvement due to better monitoring capability.

Exemplary embodiments are described below with reference to the drawings. It is obvious that the above-mentioned features and the features still to be explained hereinafter are usable not only in the respective specified combination, but also in other combinations or alone.

Identical reference signs used in the figures designate identical or at least identically-acting elements. The terms “above”, “below”, “left”, and “right”, and direction-dependent specifications derived therefrom, such as “upper side”, refer to the writing direction/reading direction of the figure designation “Figure” associated with a drawing, which is printed under the drawing on the plane of the drawing. The horizontal direction is parallel here to the writing direction of “Figure” and the vertical direction is perpendicular to the writing direction of “figure”. The writing direction is based on a horizontal script extending to the right, i.e. primarily from left to right as in, for example, Latin, English, and German.

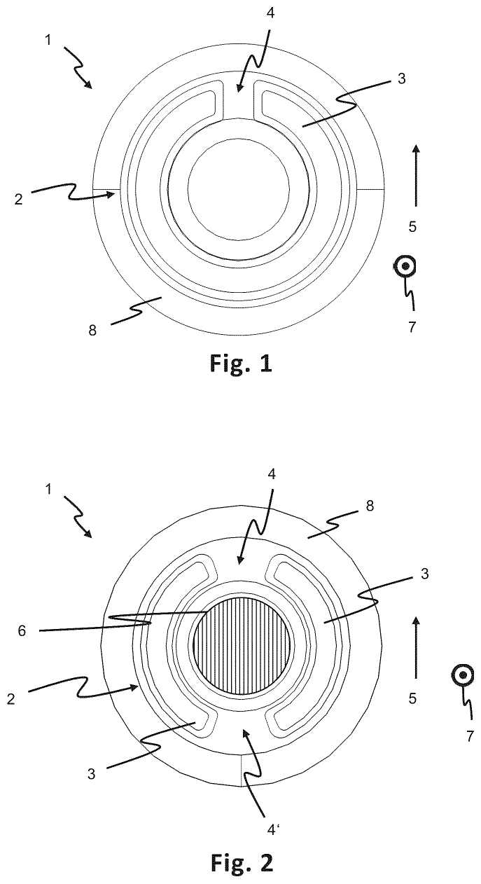

FIG. 1 shows a vertical-emitting semiconductor laser component 1 having a mesa 2, and a contact 3, which is designed as a p-contact 3 and comprises a contact opening 4. The contact opening 4 is oriented in a preferred direction 5, so that the longitudinal extension of the contact opening 4 extending vertically from top to bottom is parallel to the preferred direction 5. A surface grating 6 (cf. FIG. 2), which is not shown in FIG. 1, is arranged above the mesa 2 in the light emission direction 7. The preferred direction 5 is perpendicular to a light emission direction 7. The vertical-emitting semiconductor laser component 1 moreover comprises a trench 8, which encloses the mesa 2 and the contact 3. The preferred direction 5 is parallel to an optical axis of a semiconductor material of the vertical-emitting semiconductor laser component 1.

FIG. 2 shows a vertical-emitting semiconductor laser component 1 having a surface grating 6 oriented in the preferred direction 5, which is arranged in the area of the mesa 2 and polarizes the light emitted from the mesa 2. The vertical-emitting semiconductor laser component 1 moreover comprises a further contact opening 4′, which is arranged in the preferred direction 5 below the contact opening 4, wherein the longitudinal extension of the further contact opening 4′, extending vertically from top to bottom, is parallel to the preferred direction 5. The contact openings 4, 4′ are formed structurally identical and can be brought geometrically into congruence by rotation and translation.

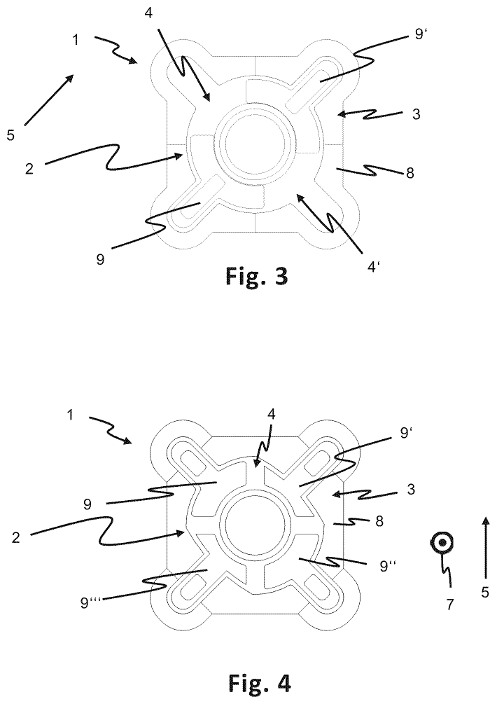

FIG. 3 shows a vertical-emitting semiconductor laser component 1 in which the contact 3 is segmented by the contact openings 4, 4′ into two contact connections 9, 9′. The contact openings 4, 4′ are oriented perpendicular to the preferred direction 5. The contact connections 9, 9′ are oriented with their longitudinal extension, which extends from bottom left to top right, along the preferred direction 5. The trench 8 is not formed circular in a top view, but rather is adapted to the geometrical course of the contact connections 9, 9′.

FIG. 4 shows a vertical-emitting semiconductor laser component 1 having four contact openings 4, which are not designated individually for reasons of clarity. The two contact openings 4 arranged opposite on the left and right are oriented perpendicular to the preferred direction 5, whereas the contact connections 9, 9′, 9″, 9′″ are oriented at 45° to the preferred direction 5, wherein the angle less than 180° is used as a reference. The opposing contact connections 9 and 9″ are dimensioned identically. The opposing contact connections 9′ and 9′″are dimensioned identically. The contact connections 9 and 9′ or 9 and 9′ arranged adjacent to one another are dimensioned differently.

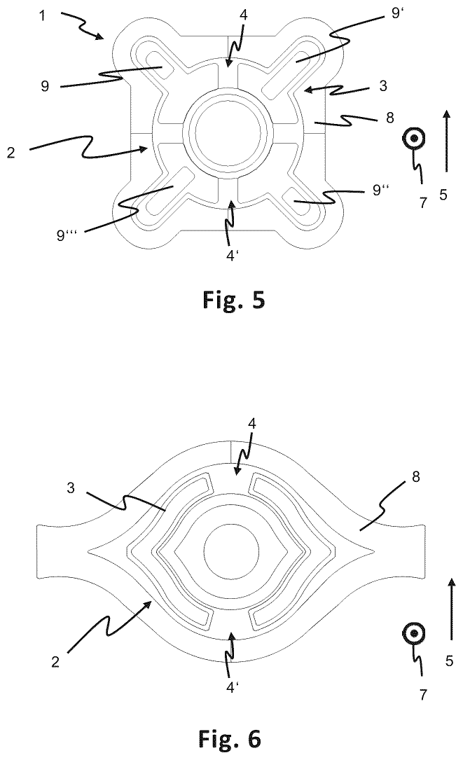

FIG. 5 shows a vertical-emitting semiconductor laser component 1 having four contact openings 4, 4′, which are not designated individually for reasons of clarity. The contact openings 4, 4′ arranged at the top and bottom in the vertical direction of the example of FIG. 5 are oriented along the preferred direction 5, whereas the contact openings 4 arranged on the left and right in the horizontal direction are arranged perpendicular to the preferred direction 5. The contact connections 9, 9′, 9″, 9′″ are formed as p-vias in the example of FIG. 5, wherein the opposing p-vias 9, 9″ and 9′, 9′″ are each dimensioned identically and adjacent p-vias 9, 9′ and 9″, 9′″ are dimensioned differently. The p-vias 9, 9′, 9″, 9′ are oriented at 45° to the preferred direction 5.

FIG. 6 shows a vertical-emitting semiconductor laser component 1 having an oval mesa 2 and an oval trench 8. The geometric course of the mesa 2 substantially corresponds to the course of the trench 8. The oval shape is substantially eye-shaped. The oval shape tapers on the left and right in the horizontal direction, perpendicular to the preferred direction 5. The contact openings 4, 4′ are oriented along the preferred direction 5.

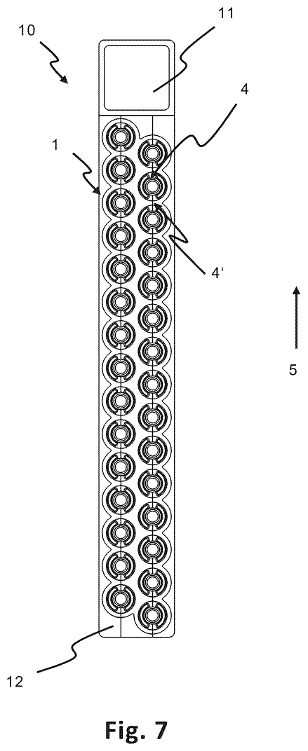

FIG. 7 shows an array 10 having a plurality of vertical-emitting semiconductor laser components 1, which are arranged in a hexagonal arrangement in two rows. Each vertical-emitting semiconductor laser component 1 comprises a surface grating 6. The array 10 comprises a wire bond connection 11 on the upper side, which is intended for electrical contacting with an external power source. The array 10 is at least partially coated with a protective layer. The outermost layer in the light emission direction 7 is formed by a non-etched cap layer 12.

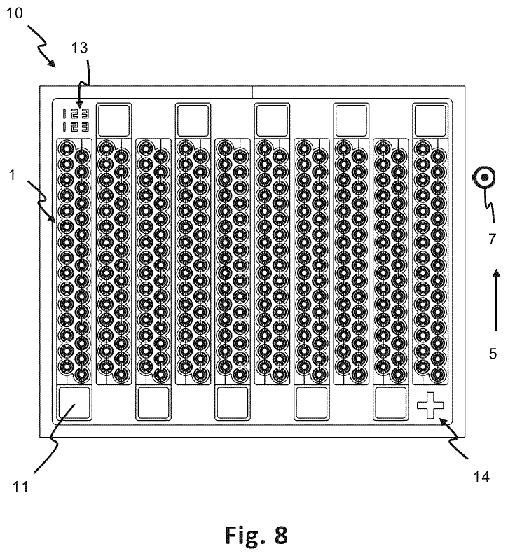

FIG. 8 shows an array 10 having a plurality of individually addressable array sections. Two array sections adjacent to one another have a polarization pivoted by 90°, wherein the vertical-emitting semiconductor laser components 1 of an individual array section have a uniform polarization. The surface gratings 6 of two array sections adjacent to one another are thus arranged orthogonally to one another. The dominant polarization orientation is accordingly rotated by 90°. The wire bond connections 11 of the array sections are alternately arranged on the upper side and lower side. The array 10 moreover comprises a chip code inscription 13 for the identification of the array 10. The array 10 moreover comprises an inscription symbol 14, which is in particular machine-readable and is used for the alignment and identification of the array 10.

The vertical-emitting semiconductor laser component 1 is produced by epitaxial layer growth. The epitaxial growth ends in an anti-resonant manner. The surface grating 6 is locally formed annularly here and etched into the final layer of the epitaxy in order to provide a polarization orientation.

In a following liftoff process step of the contact 3, which is carried out in a clean room, a lacquer layer, which is covered with metal, is removed using solvent and therefore the metal layer is also detached simultaneously. If the contact 3 were formed as a closed ring in this case, it can be the case that the solvent does not reach the interior of the ring. The light exit opening (also called a facet) remains closed here and covered with the lacquer layer and the metal layer. An open annular contact 3 therefore enables simplified processability by simplified detachment of the lacquer layer and the metal layer on the facet. The complete surface grating 6 is then coated using a thin dielectric material.

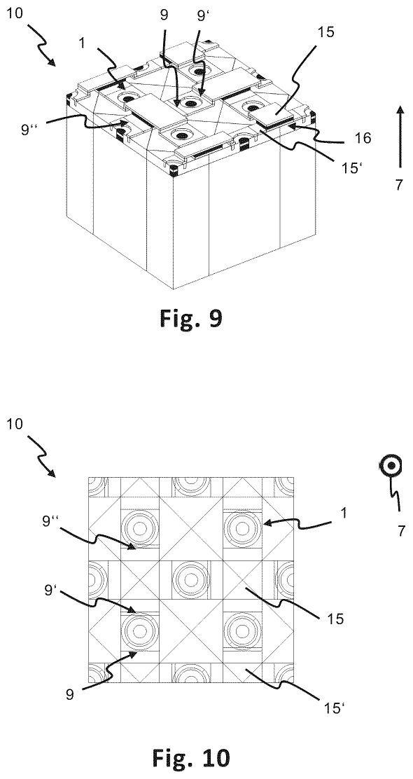

FIG. 9 shows an array 10 having intersecting conductor tracks 15, 15′, which are arranged at 90° to one another one on top of another in a fabric-like structure. The conductor tracks 15, 15′ intersect in an intersection area 16, which electrically and thermally insulates the intersecting conductor tracks 15, 15′ from one another.

FIG. 10 shows the array 10 from FIG. 9 in a top view. Each vertical-emitting semiconductor laser component 1 comprises two opposing contact connections 9, 9′, which are connected to two opposing contact connections 9″ of the adjacent semiconductor laser component 1 in each case by a conductor track 15.

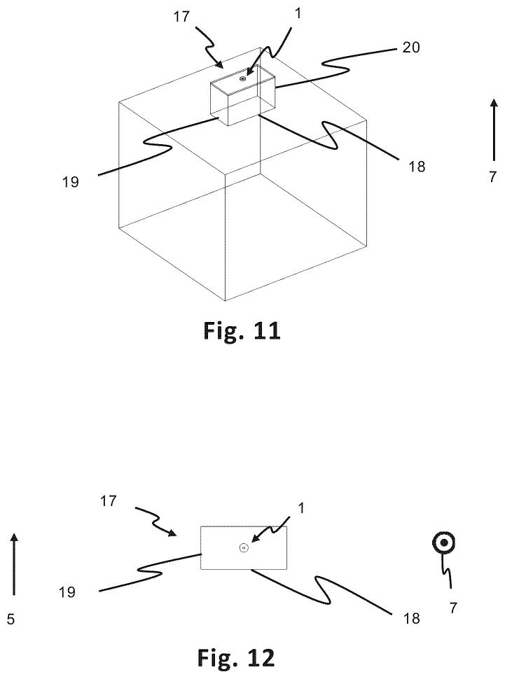

FIG. 11 shows a chip 17 having a length 18 along a longitudinal direction, which is oriented perpendicular to the light emission direction 7. The chip 17 moreover has a width 19 along a width direction, which is oriented perpendicular to the light emission direction 7. The width 19 is less than the length 18. The chip 17 has a height 20 along a height direction which corresponds to the light emission direction 7. The chip 17 comprises a vertical-emitting semiconductor laser component 1.

FIG. 12 shows the chip 17 from FIG. 11 in a top view. The width 19 along the width direction extends parallel to the preferred direction 5.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

REFERENCE SIGNS

| | | |
|---|---|---|
| 1 | vertical-emitting semiconductor laser component | 1 |
| 2 | mesa | 2 |
| 3 | contact | 3 |
| 4 | contact opening | 4 |
| 4′ | further contact opening | 4′ |
| 5 | preferred direction | 5 |
| 6 | surface grating | 6 |
| 7 | light emission direction | 7 |
| 8 | trench | 8 |
| 9 | contact connection | 9 |
| 9′ | contact connection | 9′ |
| 9′′ | contact connection | 9′′ |
| 9′′′ | contact connection | 9′′′ |
| 10 | array | 10 |
| 11 | wire bond connection | 11 |
| 12 | cap layer | 12 |
| 13 | chip code inscription | 13 |
| 14 | inscription symbol | 14 |
| 15 | conductor track | 15 |
| 15′ | conductor track | 15′ |
| 16 | intersection area | 16 |
| 17 | chip | 17 |
| 18 | length | 18 |
| 19 | width | 19 |
| 20 | height | 20 |

1. A vertical-emitting semiconductor laser component comprising:
a semiconductor material having an optical axis;
a mesa for emitting light in a light emission direction; and
a contact for electrically contacting the mesa, the contact having a contact opening arranged along a first direction;
wherein
the optical axis is arranged along the first direction.

2. A vertical-emitting semiconductor laser component comprising:
a mesa for emitting light in a light emission direction (7);
a contact for electrically contacting the mesa, the contact having a contact opening arranged along a first direction; and
a surface grating for polarizing the light, the surface grating arranged above the mesa in the light emission direction and being perpendicular or parallel to the first direction.

3. A vertical-emitting semiconductor laser component comprising
a mesa for emitting light in a light emission direction (7); and
a contact for electrically contacting the mesa, the contact having a contact opening arranged along a first direction;
wherein
the mesa has an oval shape that tapers in at least one area perpendicular or parallel to the first direction, in a top view along the light emission direction.

4. The vertical-emitting semiconductor laser component as claimed in claim 1, wherein the contact has a further contact opening arranged along the first direction.

5. The vertical-emitting semiconductor laser component as claimed in claim 1, wherein
the contact comprises a plurality of contact connections, at least two contact connections of the plurality of contact connections are dimensioned differently from each other, and one of the two contact connections is arranged along the first direction or perpendicular or at a 45° angle to the first direction.

6. The vertical-emitting semiconductor laser component as claimed in claim 5, wherein two opposing contact connections of the plurality of contact connections are dimensioned substantially identically.

7. The vertical-emitting semiconductor laser component as claimed in claim 1, further comprising
a trench, which at least partially encloses the mesa;
wherein the trench has an oval shape that tapers in at least one area perpendicular to or along the first direction, in a top view along the light emission direction.

8. The vertical-emitting semiconductor laser component as claimed in claim 1, wherein a curve course of the contact corresponds to a curve course of the mesa.

9. An array comprising a plurality of vertical-emitting semiconductor laser components as claimed in claim 1.

10. The array as claimed in claim 9, wherein the vertical-emitting semiconductor laser components are arranged substantially in an equilateral triangle in a top view along the light emission direction.

11. The array as claimed in claim 9, wherein the vertical-emitting semiconductor laser components are arranged hexagonally in relation to one another in a top view along the light emission direction.

12. The array as claimed in claim 9, wherein the vertical-emitting semiconductor laser components are arranged rectangularly in relation to one another in a top view along the light emission direction.

13. The array as claimed in claim 9, wherein each vertical-emitting semiconductor laser component comprise two contact connections,
wherein each two opposing contact connections of two vertical-emitting semiconductor laser components are connected to one another via a conductor track; and
wherein intersecting conductor tracks are arranged spaced apart from one another and offset lying one on top of another, at least within an intersection area in the light emission direction.

14. The array as claimed in claim 9, comprising a plurality of individually addressable array sections, each array section having at least one vertical-emitting semiconductor laser component,
wherein the array sections have a different polarization.

15. The array as claimed in claim 14, wherein the vertical-emitting semiconductor laser components of an individual array section have a uniform polarization.

16. A chip comprising a vertical-emitting semiconductor laser component as claimed in claim 1, wherein the chip has a height along the light emission direction, and a width and a length perpendicular to the light emission direction;
wherein the length is greater than the width, and
wherein the length and/or the width are arranged along the first direction.
